(19) United States
(12) Patent Application Publication
(10) Pub. No.: US 2025/0241124 A1
(43) Pub. Date: Jul. 24, 2025

(54) ANODE ELECTRODE FOR OLED OUTCOUPLING AND OLED COMPRISING THE SAME

(71) Applicant: KOREA UNIVERSITY RESEARCH AND BUSINESS FOUNDATION, Seoul (KR)

(72) Inventors: Byeong Kwon JU, Seoul (KR); Do Gi LIM, Asan-si (KR); Jun Young PARK, Paju-si (KR)

(21) Appl. No.: 19/034,985

(22) Filed: Jan. 23, 2025

(30) Foreign Application Priority Data
Jan. 23, 2024 (KR) 10-2024-0010030

(51) Int. Cl. H10K 50/816; H10K 50/813

(52) U.S. Cl. CPC H10K 50/816; H10K 50/813

(57) ABSTRACT

An anode electrode for organic light emission diode (OLED) outcoupling and an organic light emission diode (OLED) including the same are disclosed. The anode electrode for OLED outcoupling includes: a top anode layer; a bottom anode layer positioned below the top anode layer; and an interlayer positioned between the top anode layer and the bottom anode layer, and made of a material having a different dielectric constant depending on a material constituting the top anode layer and the bottom anode layer.

### CROSS-REFERENCE TO RELATED APPLICATION

This application claims the benefit of priority under 35 U.S.C. § 119(a) to Korean Patent Application No. 10-2024-0010030, filed on Jan. 23, 2024, the entire contents of which is incorporated herein by reference.

### BACKGROUND

### (a) Technical Field

The present disclosure relates to an anode electrode for organic light emission diode (OLED) outcoupling and an OLED including the same.

### (b) Background Art

An organic light emission diode (OLED) is one of the optical devices used in display applications, and is widely applied to TVs, monitors for IT devices, and mobile displays. Recently, major manufacturers such as Meta, Apple, and Samsung are accelerating the development of new products for augmented reality (AR), virtual reality (VR), and mixed reality (MR).

In the case of VR headsets, an optical device should have a high resolution of up to 2000 ppi (Pixels per Inch) and 1000 nit brightness to provide virtual reality to a user. Therefore, the optical device requires fine-pitch pixels and high outcoupling efficiency, and recently, a 5100 ppi resolution panel with a vertically stacked structure has been sampled. An OLEDo is one of the candidates for AR, VR optical devices, and has a structure in which an LED is stacked on a silicon wafer.

In a display panel process, two devices are manufactured on a silicon wafer in the semiconductor process for fine-pitch pixels instead of glass which is a traditional substrate. Major display panel manufacturers that developed OLEDos, such as Sony, Samsung Display, LG Display, BOE, and Kopin, are aggressively approaching the supply of optical components for mass production of Meta which is an Apple's VR headset.

AR displays require high outcoupling efficiency, and an outcoupling efficiency loss is classified into a substrate mode, waveguide mode, and surface plasmon polariton (SPP) mode. In the substrate mode and waveguide mode, due to the mismatch of the refractive index of each layer stacked, incident light causes total internal reflection at an interface between a high refractive index layer and a low refractive index layer. However, SPP is an electron vibration at an interface between a dielectric material and a metal that absorbs photon energy from the incident light.

Although much research has been conducted for decades to improve the outcoupling efficiency of the OLED, no structural improvement has been made for SPP excitation, despite the fact that SPP loss accounts for approximately 30% of the total emission energy of the OLED.

### SUMMARY OF THE DISCLOSURE

The present disclosure is to provide an anode electrode for organic light emission diode (OLED) outcoupling and an OLED including the same.

In addition, the present disclosure is to provide an anode electrode for OLED outcoupling and an OLED including the same, which can improve light efficiency by reducing SPP loss occurring in an anode metal electrode among OLED light losses.

According to an aspect of the present disclosure, there is provided an anode electrode for organic light emission diode (OLED) outcoupling and an OLED including the same.

According to one embodiment of the present disclosure, there is provided an anode electrode for organic light emission diode (OLED) outcoupling, including: a top anode layer; a bottom anode layer positioned below the top anode layer; and an interlayer positioned between the top anode layer and the bottom anode layer, and made of a material having a different dielectric constant depending on a material constituting the top anode layer and the bottom anode layer.

The top anode layer may be formed with a two-dimensional pattern array in which holes having a predetermined size are formed at predetermined intervals, and a shape of the holes may be formed in a circular or polygonal shape.

The bottom anode layer may be formed with a two-dimensional pattern array in which holes having a predetermined size are formed at predetermined intervals, and the holes formed in the bottom anode layer may be arranged to be staggered with the holes formed in the top anode layer.

The size of the hole may be smaller than a wavelength of incident light, and the hole may be formed in a range of λ>diameter≥μ/3, and λ is the wavelength of the incident light.

A thickness of the top anode layer may be 40 nm or less, and a thickness of the bottom anode layer may be 50 nm or more.

According to another aspect of the present disclosure, there is provided an organic light emission diode including: an anode electrode layer formed on a substrate; an organic layer formed on the anode electrode layer; and a cathode electrode layer formed on the organic layer, in which the anode electrode layer includes a top anode layer; a bottom anode layer positioned below the top anode layer; and an interlayer positioned between the top anode layer and the bottom anode layer, and made of a material having a different dielectric constant depending on a material constituting the top anode layer and the bottom anode layer.

By providing an anode electrode for OLED outcoupling and an OLED including the same according to an embodiment of the present disclosure, an SPP loss occurring in an anode metal electrode among OLED light losses can be reduced, thereby improving light efficiency.

### BRIEF DESCRIPTION OF DRAWINGS

FIG. 1 is a diagram illustrating a structure of an anode electrode for OLED outcoupling according to one embodiment of the present disclosure.

FIG. 2 is a diagram illustrating in detail a double layer structure according to one embodiment of the present disclosure.

FIGS. 3A to 5B are diagrams comparing light efficiencies according to hole spacing of a two-dimensional pattern array formed on a top anode layer according to one embodiment of the present disclosure.

FIGS. 6A to 7C are diagrams illustrating results of analyzing light efficiencies of upper and lower surfaces of the top anode layer according to one embodiment of the present disclosure.

FIG. 8 is a diagram comparing light efficiencies according to the hole spacing, a hole diameter, and a duty cycle according to one embodiment of the present disclosure.

FIGS. 9A and 9B are diagrams comparing light efficiencies according to a thickness of the top anode layer according to one embodiment of the present disclosure.

FIGS. 10A an 10B are diagrams comparing light efficiencies according to a material of the top anode layer according to one embodiment of the present disclosure.

FIG. 11A to FIG. 12D are diagrams comparing light efficiencies according to a thickness of an interlayer according to one embodiment of the present disclosure.

FIGS. 13A to 13C are diagrams comparing light efficiencies according to a dielectric constant and refractive index of the interlayer according to one embodiment of the present disclosure.

FIGS. 14A to 14C are diagrams comparing light efficiencies according to a thickness and material of a bottom anode layer according to one embodiment of the present disclosure.

FIGS. 15A and 15B are diagrams comparing and explaining a light path according to one embodiment of the conventional art and the present disclosure.

FIG. 16 is a diagram illustrating an anode electrode structure having a double layer structure according to another embodiment of the present disclosure.

FIGS. 17A to 17D are diagrams illustrating results of comparing a normalized far field and peak wavelength by combining two types of top anode layer and bottom anode layer, Al and Ag, respectively, according to one embodiment of the present disclosure.

### DETAILED DESCRIPTION

In the present specification, singular expressions include plural expressions unless the context clearly indicates otherwise. In the present specification, terms such as “consist of” or “include” should not be construed as necessarily including all components or steps described in the specification, and should be construed that some of the components or steps may not be included, or may further include additional components or steps. In addition, terms such as “. . . unit”, “module”, and the like described in the specification mean a unit that processes at least one function or operation, which may be implemented by hardware or software, or by a combination of hardware and software.

Hereinafter, embodiments of the present disclosure will be described in detail with reference to the attached drawings.

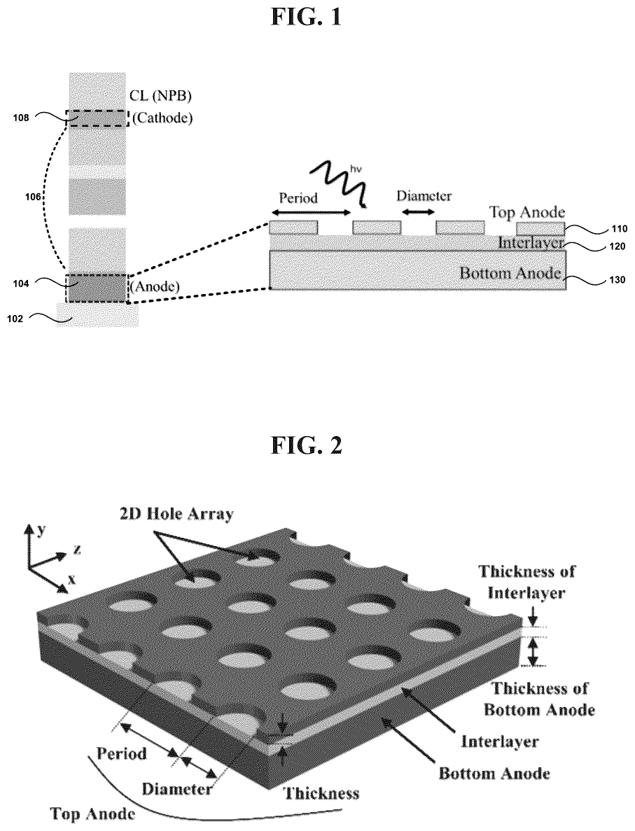

FIG. 1 is a diagram illustrating a structure of an anode electrode for OLED outcoupling according to one embodiment of the present disclosure.

Referring to FIG. 1, an OLED according to one embodiment of the present disclosure includes a substrate 102, an anode layer 104, an organic layer 106, and a cathode layer 108. Since a basic structure of the OLED and an operation thereof are obvious to those skilled in the art, a description thereof will be omitted, and the anode electrode structure, which is a main argument of the present disclosure, will be described in detail.

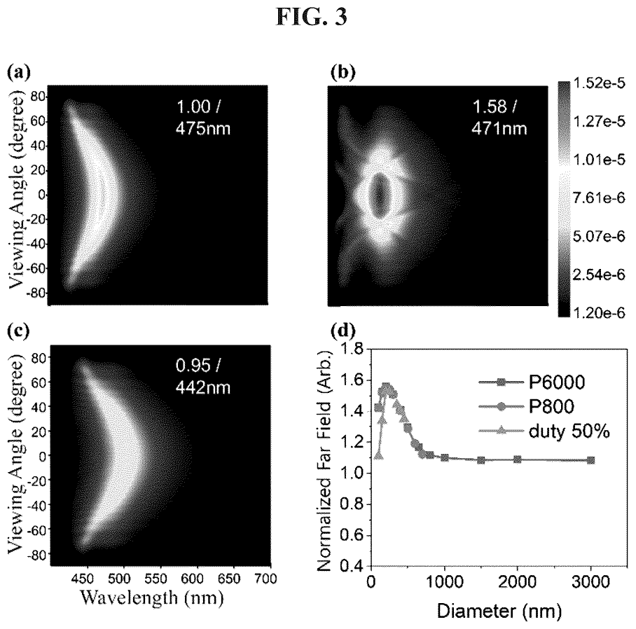

As illustrated in FIG. 1 and FIG. 2, the anode layer 104 according to one embodiment of the present disclosure may be configured to have a double layer structure.

Referring to FIGS. 1 and 2, the anode layer 104 according to one embodiment of the present disclosure includes a top anode layer 110 and a bottom anode layer 130, and an interlayer 120 that acts as a dielectric insulator of the top anode layer 110 and the bottom anode layer 130 may be formed between the top anode layer 110 and the bottom anode layer 130.

As illustrated in FIGS. 1 and 2, a two-dimensional pattern array in which holes having a predetermined size are arranged at a predetermined interval may be formed in the top anode layer 110. This two-dimensional pattern array structure may be formed as a symmetrical two-dimensional hole array as illustrated in FIG. 2. The two-dimensional pattern array structure may play an important role in supplying momentum to incident light in order to match a phase of a surface plasmon polariton (SPP) propagation constant on the metal surface. The two-dimensional pattern array formed in the top anode layer 110 is suitable for non-polarized light generated from a dipole light source, and may be formed in a square shape that is easy to arrange considering the anode design.

In one embodiment of the present disclosure, the shape of the hole may be formed in a circular or polygonal shape such as a triangle, square, or rectangle. In the following, for the convenience of understanding and explanation, it is assumed that the shape of the hole is circular and the explanation will be centered on this.

The size (diameter) of the hole formed in the two-dimensional pattern array can be formed in a size smaller than the wavelength of the incident light. The diameter of the hole is formed in a range of λ>diameter≥λ/3, and λ may be the wavelength of the incident light.

FIGS. 3A to 5B are diagrams illustrating light efficiencies according to hole spacing of a two-dimensional pattern array formed on the top anode layer 110. As illustrated in FIG. 3B, when the top anode layer 110 is a metal such as Al, an outcoupling efficiency of 1.58 times higher than that of the conventional technology (FIG. 3A) is obtained, and the outcoupling efficiency does not occur when the top anode layer is a transparent conductive oxide (TCO) such as ITO. In addition, as the diameter of the 2D hole increases, a phenomenon is observed in which the normalized far field increases and then decreases to 1. FIG. 3D is a diagram illustrating the light efficiency according to the hole spacing of the two-dimensional pattern array formed on the top anode layer 110.

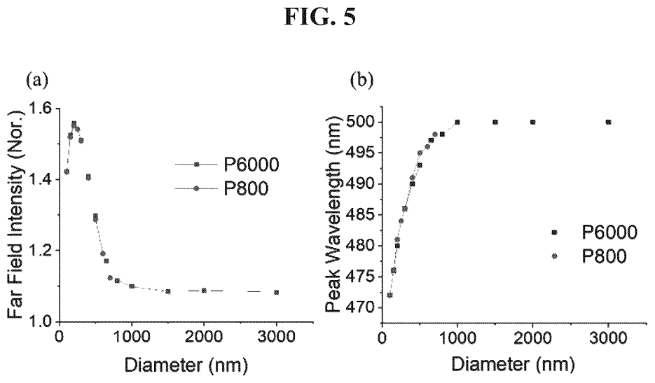

As illustrated in FIGS. 5A and 5B, it can be seen that the light efficiency is similar when the hole spacing of the two-dimensional pattern array is 700 nm and 6000 nm. In addition, it can be seen that the peak wavelength is the maximum when the hole spacing of the two-dimensional pattern array is 700 nm and 6000 nm, and the peak wavelengths match each other.

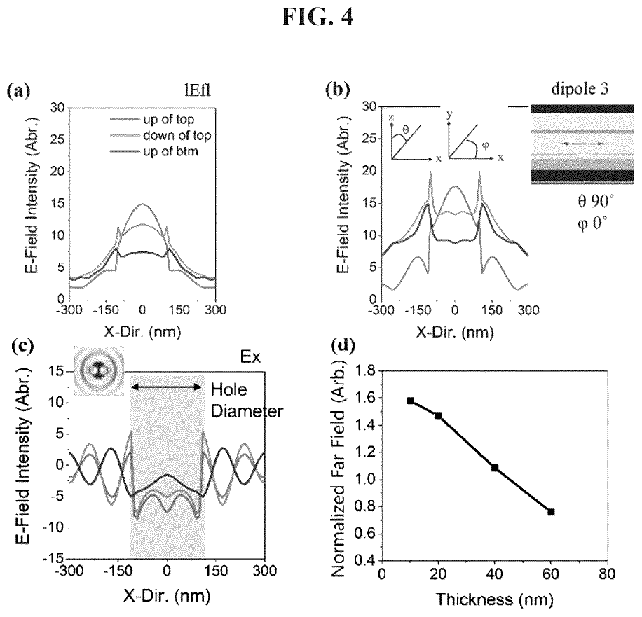

As illustrated in FIGS. 4A to 4D, an electric field is observed at three locations: above the top anode layer, below the top anode, and above the bottom anode. In FIG. 4A, the power peak below the two-dimensional hole wall below the top anode layer appears as the scattering of SPP, and the SPP below the top anode layer may be transmitted onto the bottom anode layer with the opposite negative electric field to the SPP below the top anode layer (FIG. 4C). In addition, the normalized far field (integrated enhancement factor) is changed depending on the two-dimensional hole diameter (FIG. 3D) and the top anode layer thickness (FIG. 4D). It can be seen that the outcoupling efficiency decreases sharply when the top anode layer thickness becomes twice (more than 40 nm) of the surface depth of 13.9 nm (λ=480 nm) of the Al metal. Therefore, the top anode layer should be thin enough so that SPP coupling can occur above and below the top anode layer.

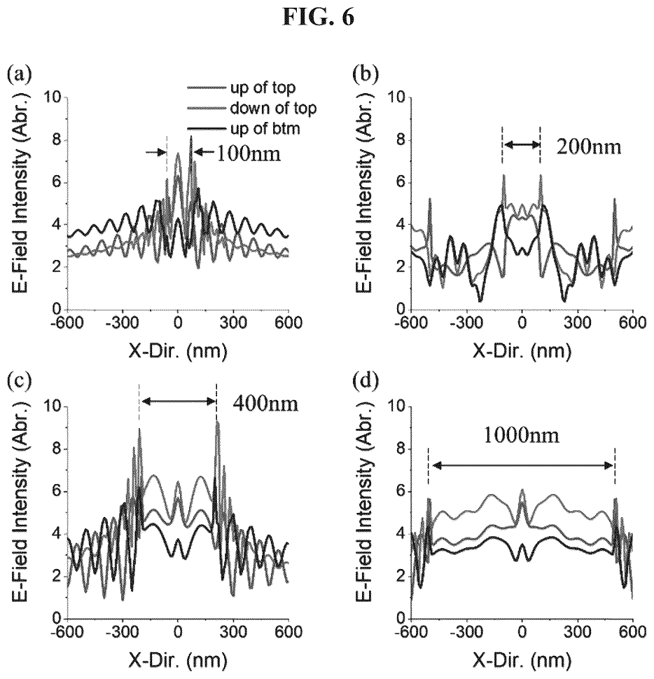

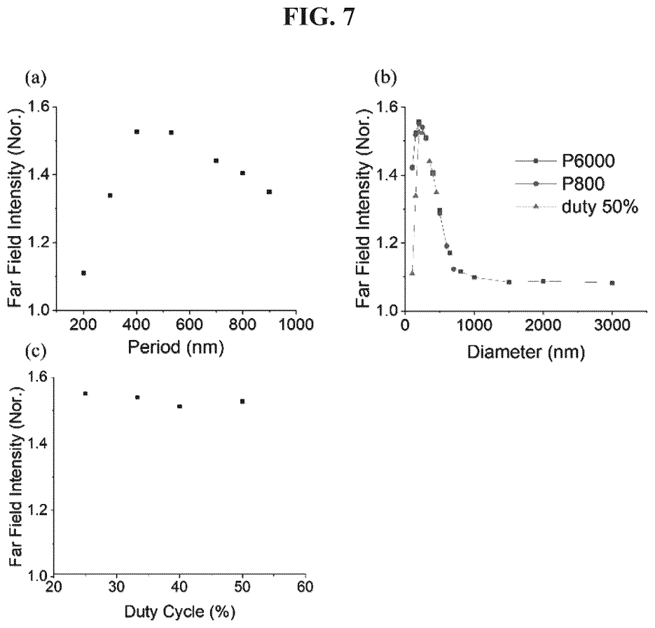

FIGS. 6A to 7C are diagrams illustrating results of analyzing light efficiencies of upper and lower surfaces of the top anode layer depending on the hole diameter according to one embodiment of the present disclosure.

It can be seen that the maximum electric field at a bottom surface of the top anode layer 110 corresponds to the hole diameter in the x direction. However, as illustrated in FIGS. 6A to 6D, when the hole diameter is 100 nm, it can be seen that the electric field shape is not separated from the hole wall surface. In other words, when the hole diameter is smaller than the wavelength of the incident light, the hole wall can trap the incident light and transmit the incident light to the bottom surface of the top anode layer 110. Depending on the hole diameter of the two-dimensional pattern array formed in the top anode layer 110, the hole may act as an antenna and a filter and transmit the incident photons to the interlayer 120. As illustrated in FIGS. 6A to 6D, when the hole diameter of the two-dimensional pattern array formed in the top anode layer 110 is larger than the wavelength of the incident light, direct transmission overwhelms an extraordinary optical transmission (EOT) phenomenon.

As illustrated in FIGS. 6A to 6D, the hole spacing in the two-dimensional pattern array formed in the top anode layer 110 appears to affect the light efficiency, but the effect of the hole spacing may be determined by the hole diameter.

It can be seen that as the two-dimensional hole diameter increases, the normalized far field increases and then decreases, eventually converging to 1. The two-dimensional hole diameter may have an optimal value for the normalized far field. In the two-dimensional pattern array dual anode structure, the electric field below the top anode layer is induced upward of the bottom anode layer, and as the diameter increases, the normalized far field is estimated to have a maximum value at the size where the SPP induced in the bottom anode layer is best formed (see FIGS. 7A to 7C).

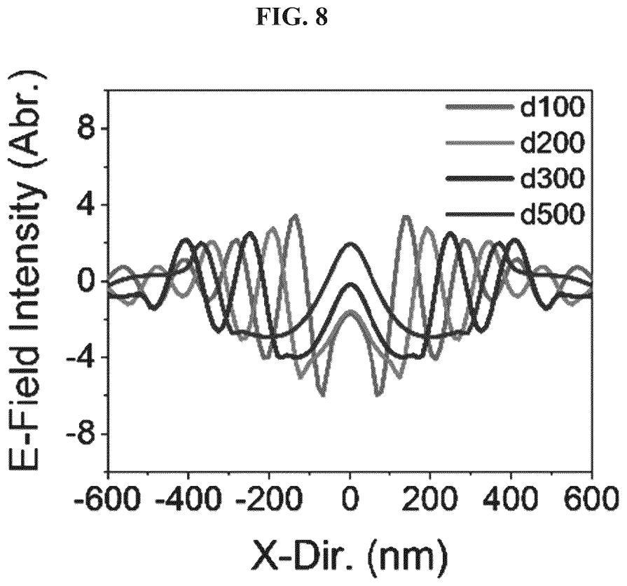

In addition, as illustrated in FIG. 8, it can be seen that a duty cycle of the two-dimensional pattern array formed in the top anode layer 110 does not affect the light efficiency. For example, the duty cycle may be calculated as “duty cycle=hole diameter/period”.

According to one embodiment of the present disclosure, the thickness of the top anode layer 110 may be formed to be 40 nm or less.

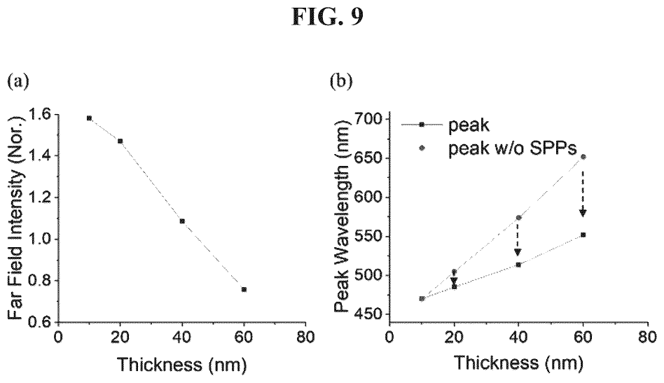

FIGS. 9A and 9B are diagrams illustrating the light efficiencies according to the thickness of the top anode layer 110. As illustrated in FIGS. 9A and 9B, it can be seen that the light efficiency changes due to the influence of the optical cavity and EOT (SPP) as the thickness of the top anode layer 110 increases. As the optical length increases, the light path increases double and the peak wavelength also increases. However, due to the SPP of the top anode layer 110, the peak wavelength increases less than the expected optical cavity effect (see FIG. 9B).

In addition, the light efficiency may vary depending on the material of the top anode layer 110. An SPP Q-factor is defined as the ratio of the material storing the incident photons, and when this is expressed as a mathematical expression, it may be expressed as Mathematical Expression 1.

$$Q - factor = ( ε ’ ) 2 / ε ” \qquad [ Mathematical Expression 1 ]$$

Here, ε′ and ε″ represent real and imaginary parts of the metal permittivity.

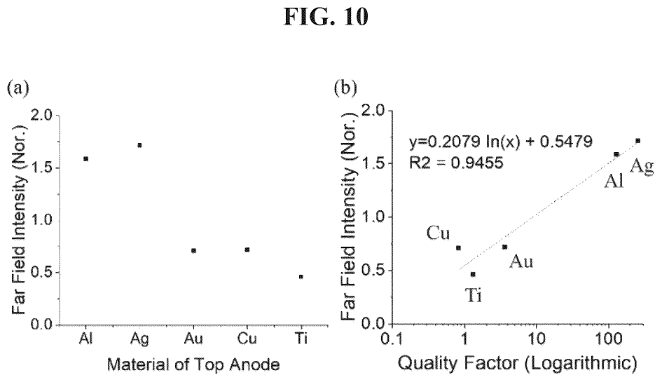

FIGS. 10A and 10B are diagrams illustrating the light efficiencies according to the material of the top anode layer. The Q-factor is logarithmically related to the far field intensity of various materials, which means that a metal with a large vibration responds to transmission due to the incident photon energy and the light efficiency increases in the dual anode structure.

Referring again to FIG. 1, the interlayer 120 is formed between the top anode layer 110 and the bottom anode layer 130, and may be composed of a dielectric material thinner than the skin depth so that the SPPs of the top anode layer 110 and the bottom anode layer 130 can be coupled.

For example, the interlayer 120 may be composed of a dielectric material of SiOx or SiNx series that is transparent in the visible light region. The interlayer 120 may be formed with a thickness of 40 nm or less, and the larger the dielectric constant, the more advantageous it is.

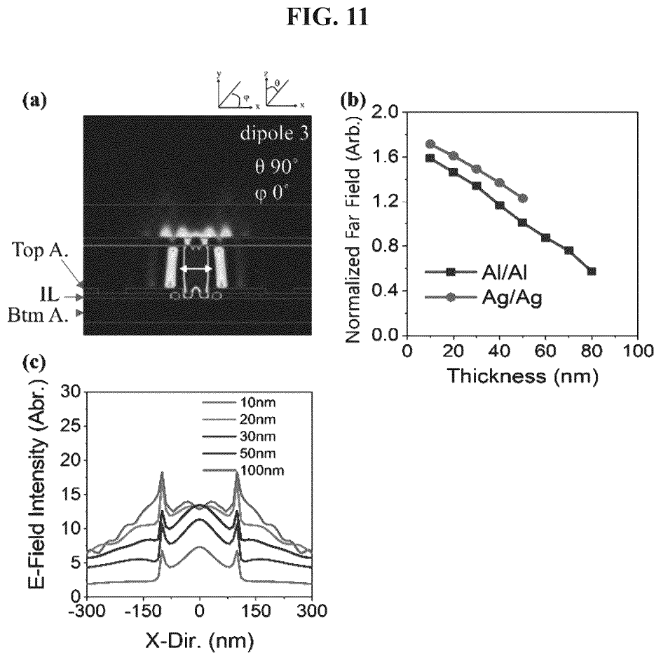

The incident light energy from a third dipole oscillates and remains until the energy is exhausted in the interlayer 120 (FIG. 11A). There is no oscillation in a first dipole, and a second dipole illustrates the same phenomenon as the third dipole. This may be a phenomenon caused by an interaction (SPP coupling) between the top anode layer 110 and the bottom anode layer 130.

In addition, as the thickness of the interlayer 120 increases, the normalized far field decreases linearly (FIG. 11B), and the electric field analysis results illustrate that the total intensity decreases (FIG. 11C).

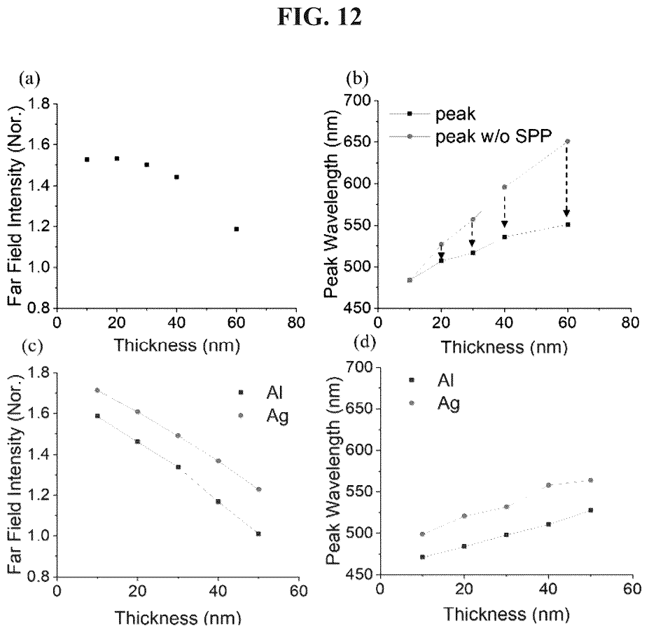

FIGS. 12A to 12D are diagrams illustrating the light efficiencies according to the interlayer thickness.

There are two requirements for determining the light efficiency in the thickness of the interlayer 120. The first is an SPP coupling effect, and the second is an optical length of an emission material layer (EML).

As illustrated in FIGS. 12A to 12D, as the thickness of the interlayer 120 increases, the light efficiency decreases and the peak wavelength increases, which is found in the top anode layer 110 and the bottom anode layer 130, respectively.

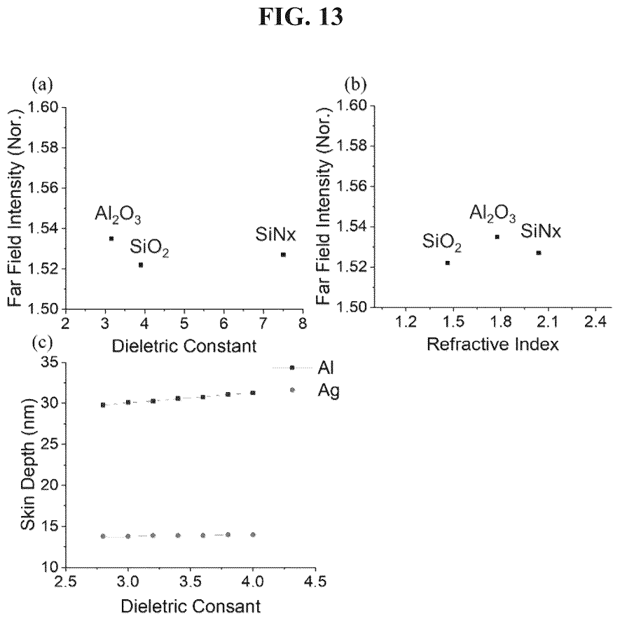

FIGS. 13A to 13C are diagrams illustrating the light efficiencies according to the dielectric constant and refractive index of the interlayer.

As illustrated in FIGS. 13A and 13B, the dielectric constant and refractive index of the interlayer 120 are not related to the light efficiency. In addition, as illustrated in FIG. 13C, the skin depth of the SPP in the metal becomes deeper as the dielectric constant increases.

In addition, it is preferable that the interlayer 120 is formed with a thickness that is thinner than or equal to the skin depth of the anode metal so that the SPP surface wave (evanescent wave) of the bottom anode layer 130 and the SPP surface wave of the top anode layer 110 overlap.

The bottom anode layer 130 is configured to reflect and combine the photon energy of the SPP generated in the top anode layer 110 and recycle the photon energy. It is preferable that the bottom anode layer 130 is formed with a material similar to the material forming the top anode layer 110 in terms of the skin depth and propagation length of the SPP, but it is not necessarily limited to the same material as the top anode layer 110.

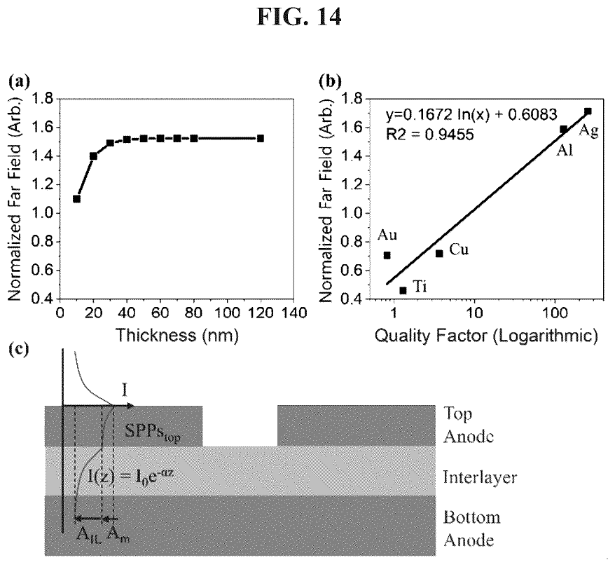

FIGS. 14A to 14C are diagrams illustrating the light efficiencies according to the thickness of the bottom anode layer. As illustrated in of FIG. 14A, when the thickness of the bottom anode layer 130 is 30 nm, which is sufficient to reflect and induce SPP in the bottom anode layer 130, the thickness at which the SPP below the top anode layer saturates the reflection efficiency is known to not affect the light efficiency.

In addition, the thickness of the bottom anode layer 130 is preferably formed to be 50 nm or more to secure the reflectivity.

FIG. 14B is a diagram illustrating the light efficiencies according to the material of the bottom anode layer 130. In the Q-factor in the material of the bottom anode layer 130, it can be seen that the light efficiency is determined by a similar tendency to the material of the top anode layer 110. For example, the top anode layer 110 and the bottom anode layer 130 may be formed of materials such as Al and Ag. However, it is not necessarily limited to this.

Moreover, it can be seen that the light efficiency is better when the skin depth of the bottom anode layer 130 is longer than that of the top anode layer 110. The long skin depth of the bottom anode layer 130 may reach the bottom surface of the top anode layer 110.

In FIG. 14C, I(z) represents the intensity of SPP in the top anode layer (I₀ represents an initial intensity in the top anode layer), a represents an attenuation coefficient of SPP (evanescent wave) in the metal and dielectric, k(ω) represents the wave vector of SPP, ω represents the angular frequency of SPP, and c represents the speed of light.

As illustrated in FIG. 14B, it can be seen that the normalized far field varies depending on the metal material, and tends to match the Q-factor value.

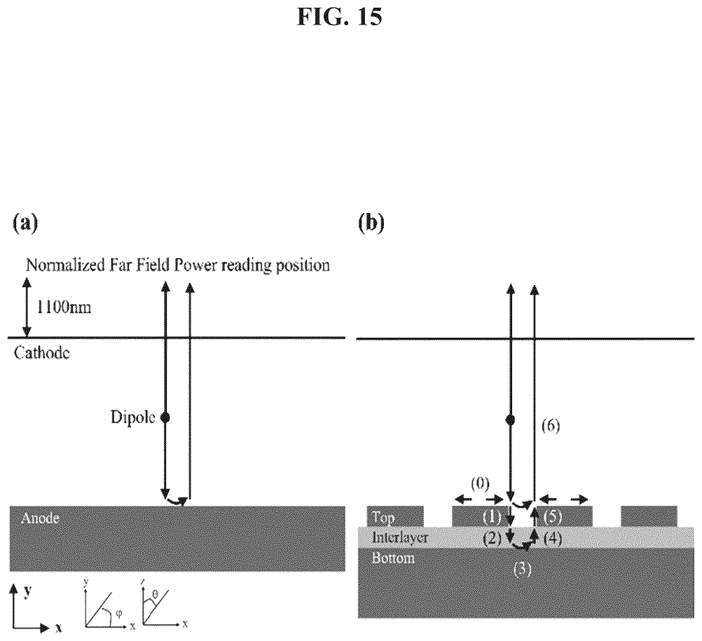

In this way, when the anode electrode is configured with a double layer structure of the top anode layer 110 and the bottom anode layer 130, the light path is as illustrated in FIGS. 15A and 15B.

FIG. 15A is a diagram illustrating the light path of a conventional anode electrode, and FIG. 15B is a diagram illustrating the light path of an anode layer 104 having a double layer structure according to one embodiment of the present disclosure.

As illustrated in FIG. 15B, in the dual anode structure having the two-dimensional pattern array as described above, the outcoupling efficiency may be increased due to the SPP excitation of the top anode layer 110 at positions (5) and (6) and the SPP coupling and reflection (position (3)) of the bottom anode layer 130. The position (5) is a recycled energy path through the bottom anode layer 130, and the position (6) represents the direct SPP excitation in the top anode layer 110 due to the two-dimensional pattern array structure. In addition, the interlayer 120 may transfer the energy of SPP generated in the top anode layer 110 to the bottom anode layer 130 (position (2)) and then transfer the energy of SPP again in the reverse direction (position (4)). For example, assuming that the wavelength of the incident light is 480 nm, the incident light (λ_{inc}=480 nm) for the top anode layer 110 generates the SPP at the interface between the metal and the interlayer 120. The wavelength of the SPP (for example, λₛₚ of Al) is 460 nm shorter than the incident light due to the dielectric momentum of the metal from the SPP. The EOT passes through the hole formed in the top anode layer 110 and propagates to the interlayer 120, and the SPP may be induced due to the interaction with the interlayer 120 on the lower surface of the top anode layer 110.

The wavelength of the SPP on the upper and lower surfaces of the top anode layer 110 varies depending on the dielectric constant of the metal, and the size of EOT may be maximized by the same wavelength of the SPP on the upper and lower surfaces of the top anode layer 110.

In addition, the EOT of the hole of the two-dimensional pattern array of the top anode layer 110 is delayed in phase due to the thickness and refractive index of the interlayer 120, and this phase difference may determine the degree to which the SPP of the top anode layer 110 and the bottom anode layer 130 match. The phase difference may be calculated as in Mathematical Expression 2.

$$ϕ = d * n / {λ}_{0} \qquad [ Mathematical Expression 2 ]$$

Here, d represents the depth of the interlayer, n represents the refractive index, and λ₀ represents the wavelength of the incident light in a vacuum.

In addition, in order to estimate the outcoupling efficiency in the two-dimensional pattern array dual anode structure, the position of the normalized far field is set to a position above 1100 nm at the cathode, and the unpolarized light is composed of three-directional dipoles. It is assumed that the first dipole is θ=90°/φ=90°, the second dipole is θ=0°/φ90, and the third dipole is θ=90°/φ=0°.

The outcoupling efficiency and the normalized far field (F) may be defined as in Mathematical Expressions 3 and 4.

$${η}_{out} = \int \int {\sum }_{θ = 1}^{n} \vert E 2 * θ2 \vert \hat{} 2 dxdz / \int \int {\sum }_{θ = 1}^{n} \vert E 1 * θ1 \vert \hat{} 2 dxdz \qquad [ Mathematical Expression 3 ]$$

$$F = {η}_{sdh} / {η}_{ref} \qquad [ Mathematical Expression 4 ]$$

Here, ηₒᵤₜ represents the outcoupling efficiency of the OLED, E1 and E2 represent the electric field intensities of the dipole and the far field, and θ1 and θ2 represent the incident angles of E1 and E2, x and z represent the integration planes for collecting the power of the far field, and η2dh and ηref represent the outcoupling efficiencies of the 2D pattern array dual anode structure and the conventional structure, respectively.

According to another embodiment of the present disclosure, as illustrated in FIG. 16, the bottom anode layer may also have a two-dimensional pattern array structure in which holes having a predetermined diameter are arranged at a predetermined interval, similar to the top anode layer.

In the case where the bottom anode layer is also formed as a two-dimensional pattern array structure, the holes of the bottom anode layer and the holes of the top anode layer may be arranged alternately for constructive interference, as illustrated in FIG. 16.

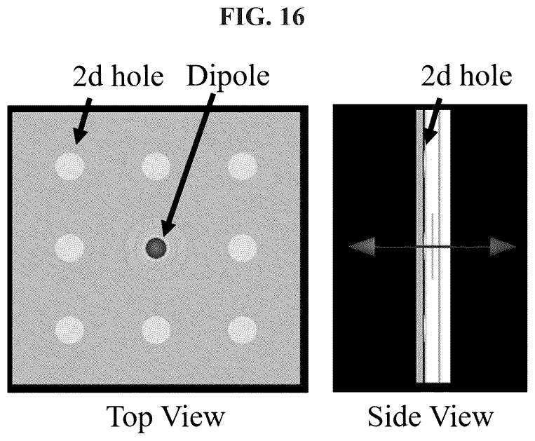

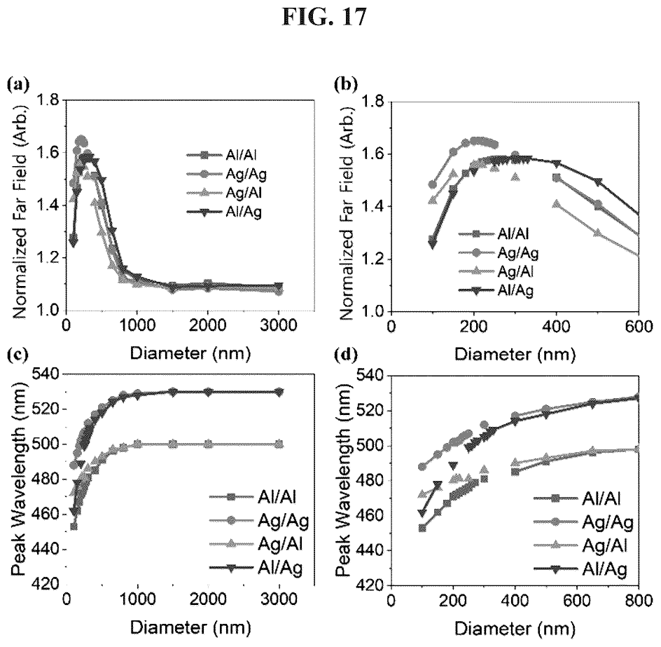

FIGS. 17A to 17D and Table 1 are diagrams illustrating the results of comparing the normalized far field and peak wavelength by combining two types of top anode layer and bottom anode layer, Al and Ag, respectively.

TABLE 1

| Top/Bottom Anode Materials | | Ag/Ag | Al/Ag | Al/Al | Ag/Al |
|---|---|---|---|---|---|
| Normalized Far-Field Power | | 1.651 | 1.584 | 1.582 | 1.559 |
| 2D Hole Diameter (nm) | | 210 | 310 | 260 | 210 |
| Peak Wavelength | Maximum (λₘ) | 502 | 506 | 478 | 481 |
| (nm) | Saturation (λₛₐₜ) | 530 | 530 | 500 | 500 |

The material of the top anode layer 110 may determine the hole diameter for maximum far-field power (Ag top anode layer/Ag bottom anode layer-diameter 210 nm, Ag top anode layer/Al bottom anode layer-diameter 210 nm, Al top anode layer/Al bottom anode layer-diameter 260 nm, Al top anode layer/Ag bottom anode layer-diameter 310 nm). The hole diameter may be determined by the wavelength of the SPP (Ag 429.3 nm, Al 460 nm).

As illustrated in FIG. 4C, the positive electric field of the SPP below the top anode layer may induce the negative electric field above the bottom anode layer. Accordingly, it can be seen that the shorter SPP wavelength of Ag exhibits the maximum normalized far field in the two-dimensional hole diameter smaller than that of Al.

The bottom anode layer material can determine the maximum normalized far field (m) and the saturation wavelength (λsat). The maximum wavelength is the excitation or coupling wavelength of the SPP in the top and bottom anode layers. In order for the SPPs of the top and bottom anode layers to be coupled, the SPP transfer constant of the top anode layer with momentum due to the two-dimensional pattern array should be equal to the SPP transfer constant of the bottom anode layer including the phase change due to the interlayer. The two design parameters of the two-dimensional pattern array of the top anode layer, the interlayer, and the materials of the top and bottom anode layers may interact to form the maximum wavelengths, respectively.

The present disclosure has been described with a focus on examples thereof. Those skilled in the art to which the present disclosure belongs will understand that the present disclosure can be implemented in modified forms without departing from the essential characteristics of the present disclosure. Therefore, the disclosed embodiments should be considered from an illustrative perspective rather than a restrictive perspective. The scope of the present disclosure is set forth in the claims, not the foregoing description, and all differences within the scope equivalent thereto should be interpreted as being included in the present disclosure.

What is claimed is:

1. An anode electrode for organic light emission diode (OLED) outcoupling, the anode electrode comprising:
a top anode layer;
a bottom anode layer positioned below the top anode layer; and
an interlayer positioned between the top anode layer and the bottom anode layer, and made of a material having a different dielectric constant depending on a material constituting the top anode layer and the bottom anode layer.

2. The anode electrode of claim 1, wherein the top anode layer is formed with a two-dimensional pattern array in which holes having a predetermined size are formed at predetermined intervals, and
a shape of the holes is formed in a circular or polygonal shape.

3. The anode electrode of claim 2, wherein the bottom anode layer is formed with a two-dimensional pattern array in which holes having a predetermined size are formed at predetermined intervals, and
the holes formed in the bottom anode layer are arranged to be staggered with the holes formed in the top anode layer.

4. The anode electrode of claim 1, wherein the size of the hole is smaller than a wavelength of incident light, and
the hole is formed in a range of λ>diameter≥λ/3, and λ is the wavelength of the incident light.

5. The anode electrode of claim 1, wherein a thickness of the top anode layer is 40 nm or less, and
a thickness of the bottom anode layer is 50 nm or more.

6. An organic light emission diode, comprising:
an anode electrode layer formed on a substrate;
an organic layer formed on the anode electrode layer; and
a cathode electrode layer formed on the organic layer,
wherein the anode electrode layer includes:
a top anode layer;
a bottom anode layer positioned below the top anode layer; and
an interlayer positioned between the top anode layer and the bottom anode layer, and made of a material having a different dielectric constant depending on a material constituting the top anode layer and the bottom anode layer.
